(19) United States
(12) Patent Application Publication
(10) Pub. No.: US 2006/0191782 A1
(43) Pub. Date: Aug. 31, 2006

(54) Magnetron sputtering coater and method of improving magnetic field uniformity thereof

(76) Inventors: Tun-Ho Teng, Tao-Yuan Hsien (TW); Chun-Hsia TENG HUANG, Taipei Hsien (TW); Kei-Hsiung YANG, Tao-Yuan Hsien (TW); Cheng-Chung Lee, Tao-Yuan Hsien (TW); Hsin-Yi Chen, Taipei City (TW); Wei-Chou CHEN, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/908,068

(22) Filed: Apr. 26, 2005

(30) Foreign Application Priority Data
Feb. 25, 2005 (TW) 094105832

(51) Int. Cl. C23C 14/32; C23C 14/00

(52) U.S. Cl. 204/192.1; 204/298.16

(57) ABSTRACT

A method of improving the magnetic field uniformity of a magnetron sputtering equipment is disclosed. The method includes providing an equipment having a magnetic field generating device and a magnetic field receiving surface; utilizing the equipment multiple times to acquire the magnetic field intensity distribution on the magnetic field receiving surface; preparing a compensation plate corresponding to the magnetic field intensity distribution, such that the area of the compensation plate corresponding to the area of the magnetic field receiving surface with stronger magnetic field has a stronger ferromagnetic property and the area corresponding to the area of the magnetic field receiving surface with weaker magnetic field has a weaker ferromagnetic property; and installing the compensation plate between the magnetic field generating device and the magnetic field receiving surface for improving the magnetic field uniformity of the magnetic field receiving surface.

### BACKGROUND OF INVENTION

1. Field of the Invention

The present invention relates to a method of improving the magnetic field uniformity of an equipment, and more particularly, to a method of improving the magnetic field uniformity of a magnetron sputtering coater.

2. Description of the Prior Art

Sputtering is a method of fabricating metal and dielectric thin films. Essentially, sputtering is achieved by producing plasma within the chamber of a sputtering coater, bombarding a target by accelerating the ions of the plasma thereby causing the target material to sputter toward a substrate from the front surface of the target, and forming a metal or a dielectric film deposition over the surface of the substrate.

Despite having numerous designs for a magnetic controlling system, magnetron sputtering coater commonly used in industry today generally have various disadvantages including: poor magnetic field uniformity in the plasma working area of the reaction chamber, low usage rate of the target material, and poor uniformity of the films produced.

Please refer to FIG. 1. FIG. 1 is a schematic diagram showing a conventional magnetron sputtering coater 10 according to the prior art. As shown in FIG. 1, the magnetron sputtering coater 10 includes a reaction chamber 11, a target 18, a susceptor 13, and a magnet 14, in which the target 18 is composed of a back plate 12 and a target material 16. In most cases, after the air is extracted from the reaction chamber 11 to the outside by utilizing a vacuum pump (not shown), plasma carrying an electrical charge, such as positive argon ions, are brought into the chamber 11. Since the target 18 and the susceptor 13 are connected separately to the negative and positive electrode, a potential gradient is created there between. Next, positive argon ions are utilized to bombard the target material 16 surface by utilizing the target material 16 as a negative electrode. As a result, the atoms of the target material 16 are sputtered and deposited on a substrate 15 disposed on the susceptor 13 to form a thin film.

By oscillating movement parallel to and at the back of the target 18, the magnet 14 is attempted to control the magnetic field to improve the deposition uniformity and speed of the thin film to the surface of the substrate 15. However, the analysis of the thin film deposited on the surface of the substrate 15 and the corrosion condition of the target material after the sputtering process shows that the uniformity of the sputter film is poor and the corrosion caused on the target is also uneven. Please refer to FIG. 2. FIG. 2 is a schematic diagram showing the corrosion result of the surface of the target after numerous sputtering processes are performed on the target according to the prior art. As shown in FIG. 2, the corrosion on the upper and lower ends of the target material 16 is much faster than other regions, and after the corrosion reaches the back of the target material 16, the entire target 18 will become unusable.

U.S. Pat. No. 6,793,785 discloses a magnetron oscillating-scanning sputter, in which a demagnetization device is installed on the two ends of a magnet to reduce the strength of the magnetic field at that particular location and solve the uneven distribution problem of the magnetic field strength. Please refer to FIG. 3. FIG. 3 is a schematic diagram showing the structure of the magnet installed with a demagnetizing device according to the prior art. As shown in FIG. 3, a double-hook demagnetization device 37a or a bone-shaped demagnetization device 37b is installed on two ends of a magnet 34. Despite the effectiveness of this design, the magnet has to be wrapped for each usage and often the magnet has to be replaced by a new one for a different sputtering process.

Hence, it becomes an important task for the industry to provide a solution to improve the magnetic field uniformity of the magnetic field generating device and solve the problems such as the low usage rate of the corresponding target material and the poor uniformity of the thin films produced.

### SUMMARY OF INVENTION

It is therefore an objective of the present invention to provide a method for improving the magnetic field uniformity of a magnetron sputtering coater, the usage rate of the magnetron sputtering target material, and the uniformity of the finished thin films.

It is therefore another objective of the present invention to provide a method for improving the magnetic field uniformity of a magnetic generating device, and particularly, for increasing the magnetic field uniformity on the working surface of the magnetic field generating device.

It is therefore another objective of the present invention to provide a magnetron sputtering coater for providing an improvement of the magnetic field uniformity to the substrate.

According to the present invention, a method of improving the magnetic field uniformity of a magnetron sputtering coater includes: providing a magnetron sputtering coater, wherein the magnetron sputtering coater further includes: a target, wherein the front of the target further comprises a target material; a susceptor situated corresponding to the target, wherein the susceptor supports a substrate for depositing a target material thereon; and a magnetic field generating device located on the back of the target for generating a magnetic field and controlling the deposition of the target material; and installing a compensation plate between the target and the magnetic field generating device, wherein the compensation plate is comprised of a substrate having at least one magnetic field compensation area thereon, such that the ferromagnetic property of the magnetic field compensation area is different from the ferromagnetic property of the substrate.

Additionally, the present invention provides a method of improving the magnetic field uniformity of an equipment having a magnetic field generating device. The method includes: providing an equipment, wherein the equipment comprises a magnetic field generating device and a magnetic field receiving surface; utilizing the equipment numerous times for obtaining the magnetic field strength distribution of the magnetic field receiving surface; providing a compensation plate according to the magnetic field strength distribution of the magnetic field receiving surface, such that the area of the compensation plate corresponding to area of the magnetic field receiving surface having a stronger magnetic field comprises a stronger ferromagnetic property, and the area of the compensation plate corresponding to the area of the magnetic field receiving surface having a weaker magnetic field comprises a weaker ferromagnetic property; and installing the compensation plate between the magnetic field generating device and the magnetic field receiving surface for improving the magnetic field uniformity of the magnetic field receiving surface.

Moreover, the present invention discloses a magnetron sputtering coater, in which the magnetron includes a target, wherein the front of the target further comprises a target material; a susceptor situated corresponding to the target, wherein the susceptor supports a substrate for depositing a target material thereon; a magnetic field generating device located on the back of the target for generating a magnetic field and controlling the deposition of the target material; and a compensation plate installed between the target and the magnetic field generating device, wherein the compensation plate is comprised of a substrate having at least one magnetic field compensation area thereon, such that the ferromagnetic property of the magnetic field compensation area is different from the ferromagnetic property of the substrate.

In contrast to the conventional method, the present invention utilizes a more passive approach to install a compensation plate on an equipment for adjusting the uniformity of the magnetic field distribution. Additionally, the present invention is applicable to substrates with different sizes and shapes, magnets with different shapes and control methods, and magnetron sputtering coaters with one or more magnets. Ultimately, the present invention is able to improve the usage rate of the target material and the uniformity of the films produced under different usage habits and different target materials being used.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram showing a conventional magnetron sputtering coater according to the prior art.

FIG. 2 is a schematic diagram showing the corrosion result of the surface of the target after numerous sputtering processes are performed on the target according to the prior art.

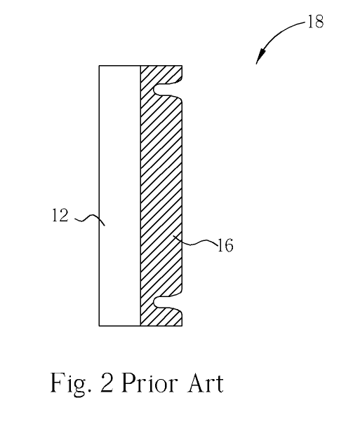

FIG. 3 is a schematic diagram showing the structure of the magnet with a demagnetizing device according to the prior art.

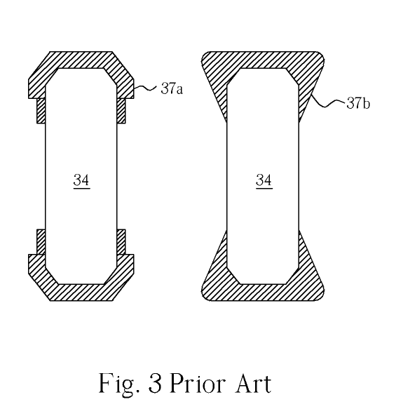

FIG. 4 is a schematic diagram showing the corrosion condition of the target surface of a magnetron sputtering coater after the sputter is utilized numerous times.

FIG. 5 is a schematic diagram showing the corresponding size and shape of the compensation plate and the target according to the present invention.

FIG. 6 is a schematic diagram showing the structure of the compensation plate according to the preferred embodiment of the present invention.

FIG. 7 is a schematic diagram showing the cross section along line AA′ of FIG. 6.

FIG. 8 is a schematic diagram showing the structure of the compensation plate according to another embodiment of the present invention.

FIG. 9 is a schematic diagram showing the means by which the compensation plate is equipped into a magnetic field generating device according to the present invention.

### DETAILED DESCRIPTION

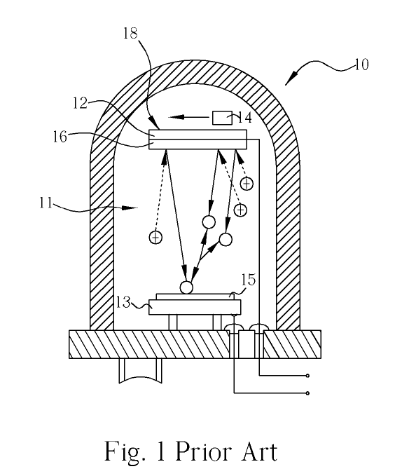

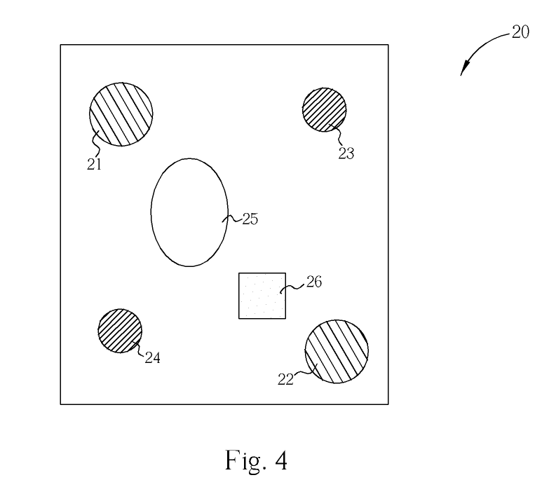

Please refer to FIG. 4 through FIG. 9. First, a magnetron sputtering coater is provided, such as a conventional magnetron sputtering coater from FIG. 1, in which the magnetron sputtering coater includes a reaction chamber 11, a target 18, a susceptor 13, and a magnet 14. Next, a sputtering process is performed at least once using the magnetron sputtering coater to cause damage on the target material. Such process is performed to cause corrosion (consumption) of the target material and the number of times to perform the process is not limited. Next, the corroded target material 20 is removed from the target 18 and by utilizing a three-dimensional photography and measurement, the damage condition of different areas of the target material 20 can be accurately measured and a damage result is finally obtained. Please refer to FIG. 4. FIG. 4 is a schematic diagram showing the corrosion map of the target surface of a magnetron sputtering coater after the sputtering coater is utilized numerous times. As shown in FIG. 4, three different degrees of corrosion are expressed. The most severe ones are areas 21 and 22 followed by less severe areas 23 and 24.The least severe ones are area 25 and 26.

Next, a compensation plate 30 is provided according to the damage map, in which the area of the compensation plate 30 corresponding to the target material with greater damage has a stronger ferromagnetic property and the area corresponding to the target material with smaller damage has a weaker ferromagnetic property. By having greater ferromagnetic property at the area corresponding to the target material with greater damage, the compensation plate 30 is able to shelter a much stronger magnetic field. Conversely, the compensation plate 30 having a weaker ferromagnetic property or even no ferromagnetic property at all at the area corresponding to the target material with smaller damage is able to compensate with a weaker magnetic field or to provide no compensation ability. As a result, a magnetic field compensation area is formed to facilitate the uniformity of the magnetic field and to maintain a uniform depletion of the target material.

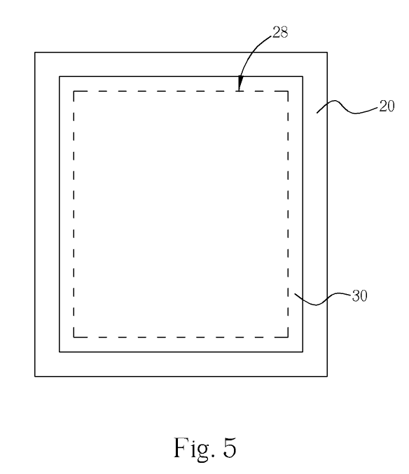

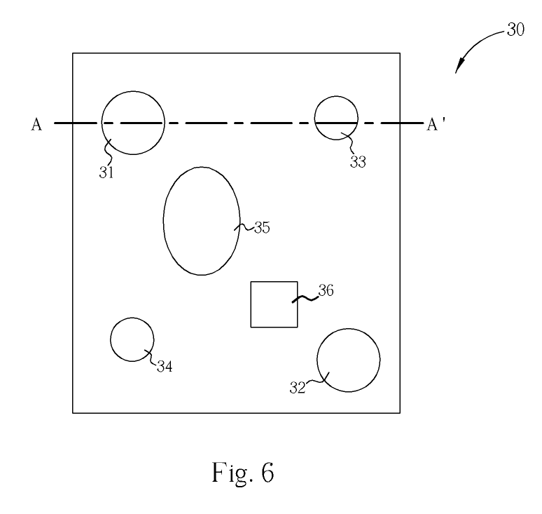

Please refer to FIG. 5. FIG. 5 is a schematic diagram showing the corresponding size and shape of the compensation plate 30 and the target according to the present invention. As shown in FIG. 5, the shape and the size of the compensation plate 30 is formed corresponding to the shape and size of the target material 20 surface, such that when the compensation plate 30 is installed, the four sides of the compensation plate 30 are located between the edges of target material 20 and the edges of a bombarding area 28 of the target material 20. Preferably, the first method of preparing the compensation plate 30 is to utilize materials with weaker or no ferromagnetic properties, such as aluminum, copper, silver, zinc, gold, carbon, lead, magnesium, platinum, chromium, manganese, tin, vanadium, tungsten, or other compound materials, as the base of the compensation plate 30. Next, materials with stronger ferromagnetic properties including iron, cobalt, nickel, or other rare earth metals, or Heusler alloy, are utilized to inlay or insert into the area corresponding to the area of the target material with greater damage. Please refer to FIG. 6. FIG. 6 is a schematic diagram showing the structure of the compensation plate 30 according to the preferred embodiment of the present invention. As shown in FIG. 6, the thickness of the area of the compensation plate 30 where the high ferromagnetic material is inserted is approximately equivalent to the thickness of other areas of the plate 30 where the high ferromagnetic material is not inserted. The area of the compensation plate 30 corresponding to the target material 20 damage can be removed mechanically, for example, by lathe works, and according to the level of the damage, high ferromagnetic materials with corresponding thickness and shapes are inserted into the compensation plate 30, such that greater damage usually requires ferromagnetic materials with larger thickness. For example, areas 31-36 schematically shown in FIG. 6 are corresponding to the corrosion areas 21-26 on the target material schematically shown in FIG. 4.

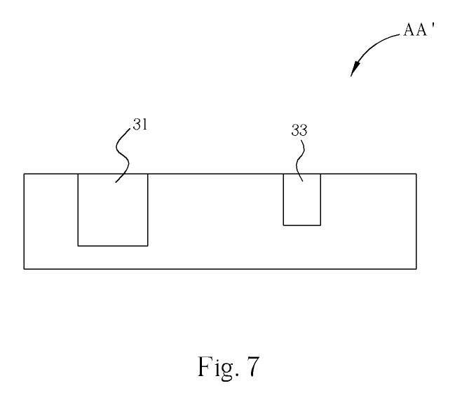

Please refer to FIG. 7. FIG. 7 is a schematic diagram showing the cross section along line AA′ of FIG. 6. As shown in FIG. 7, the depth of the area 31 where stronger ferromagnetic material is inserted is greater than the depth of the area 33 where stronger ferromagnetic material is inserted since the damage of the area 21 of the target area 20 is greater than the damage of the area 23.

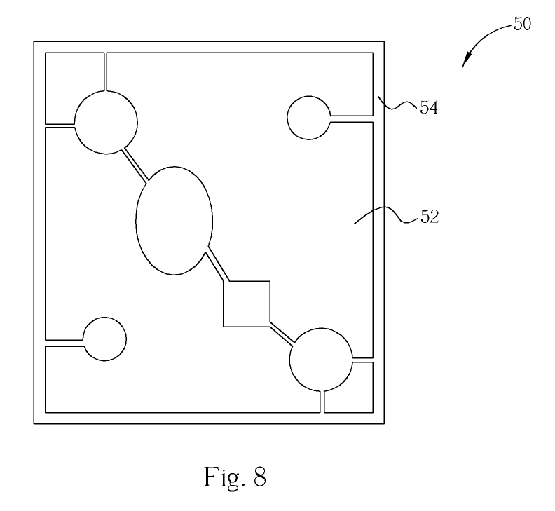

Please refer to FIG. 8, showing an alternative way to prepare the compensation plate. FIG. 8 is a schematic diagram showing the structure of the compensation plate according to another embodiment of the present invention. As shown in FIG. 8, the base compensation plate 54 is comprised of a material with stronger ferromagnetic property and a material with weaker or no ferromagnetic property is inlayed into an area 52 corresponding to the area of the target material with smaller damage to fabricate the compensation plate. Alternatively, the area 52 corresponding to the area of the target material with smaller damage can be removed completely to form the compensation plate. In general, the thickness of the strong ferromagnetic base 54 can be further adjusted to achieve the degree of demagnetization required.

Preferably, a magnetron sputtering coater is utilized to perform a plurality of sputtering processes to observe the damage map of the target material in order to fabricate the compensation plate. Alternatively, other measuring instruments can also be utilized to analyze the distribution of the magnetic field for fabricating the compensation plate.

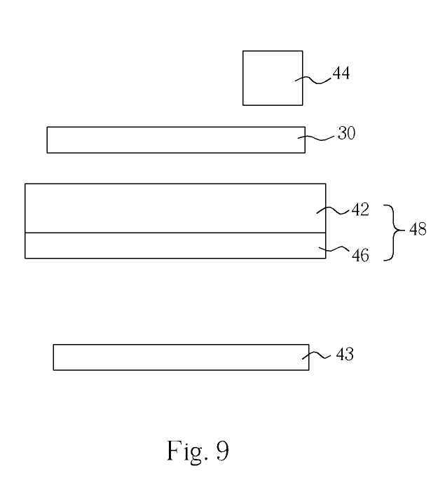

After installing the compensation plate 30 between the magnetic field generating device of the equipment and the target, the magnetic field uniformity of the target can be greatly improved. Please refer to FIG. 9. FIG. 9 is a schematic diagram showing the means by which the compensation plate is equipped into a magnetic field generating device according to the present invention. As shown in FIG. 9, the compensation plate 30 is equipped between a magnetic field generating device 44, such as a magnet, and a target 48 (including the back plate 42 and the target material 46) to adjust the magnetic field exerted on the surface of the target material 46 and to uniformly deposit the target material 46 onto s substrate located on the susceptor 43. Usually, the gap distance between the magnet 44 and the target 48 of any equipment having a magnetic field generating device, such as a magnetron sputtering coater, is adjustable. Additionally, a slot can be formed on the back cover of the reaction chamber and the compensation plate 30 is inserted into the slot from aside, in which the compensation plate 30 can be replaced freely by utilizing retainers formed on the top and bottom end of the reaction chamber. Moreover, a plurality of openings can be formed on the four edges of the compensation plate 30 to allow screws to fix the compensation plate 30 in position from the posterior end of the reaction chamber. In most cases, the thickness of the compensation plate is predetermined to be less than the gap distance between the magnet and the target to facilitate the insertion of the compensation plate 30. Nevertheless, when the thickness of the compensation plate 30 is greater than the gap distance, the magnetic field generating device can be manipulated to increase the gap distance for accommodating the compensation plate 30 and if the strength of the magnetic field equivalent to the target needs to be maintained, only the increase of the magnetic field strength is required. Ultimately, the present invention is able to provide a much simpler method for enhancing the usage of the magnetron sputtering coater, thereby increasing the overall effectiveness and efficiency of the equipment.

After the compensation plate is installed between the magnetic field generating device and the target, a plurality of sputtering process is performed while the surface of the target material is still maintained uneven from the result of the damage. Hence, the present invention is able to provide a method to adjust the insertion position and thickness of the compensation plate according to the damage map or fabricate a new compensation plate to replace the original plate for improving the uniformity of the magnetic field. Preferably, the adjustment or replacement of the compensation plate can be performed during the preventive maintenance (PM) of the equipment for facilitating the installation of the equipment and the processing time.

In general, the compensation plate of the present invention can be utilized in sputters for numerous semiconductor processes, TFT-LCD fabrication processes, and any equipment having a magnetic field generating device and a magnetic field receiving surface, such as a plasma enhanced chemical vapor deposition (PECVD) equipment, a magnetron sputtering coater, a high density plasma/inductively coupled plasma (HDP/IDP) etcher, a reaction ion etching (RIE) equipment, or a plasma cleaner. After utilizing a magnetic field detection method, or from the result of the finished thin film or etching process, information regarding the magnetic field strength distribution of the magnetic field receiving surface of the equipment can be obtained. Next, a compensation plate is fabricated according to the magnetic field strength distribution of the magnetic field receiving surface, such that the area of the compensation plate corresponding to the area of the magnetic field receiving surface with stronger magnetic field has a stronger ferromagnetic property and the area corresponding to the area of the magnetic field receiving surface with weaker magnetic field has a weaker ferromagnetic property. Finally, the compensation plate is installed between the magnetic field generating device and the magnetic field receiving surface for improving the magnetic field uniformity of the magnetic field receiving surface.

In contrast to the conventional method, the present invention utilizes a more passive and economical approach to improve the structure of the compensation plate, improve the magnetic field uniformity of the magnetron sputtering coater, effectively increase the utilization rate of the target material, and improve the uniformity of the thin film produced. Moreover, the compensation plate can be replaced conveniently according to desired sputtering processes, thereby expanding the applicability to other fabrication processes and magnetic product designs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of improving the magnetic field uniformity of a magnetron sputtering coater comprising:
providing a magnetron sputtering coater, wherein the magnetron sputtering coater further comprises:
a target, wherein the front of the target further comprises a target material;
a susceptor situated corresponding to the target, wherein the susceptor supports a substrate for depositing a target material thereon; and
a magnetic field generating device located on the back side of the target for generating a magnetic field and controlling the deposition of the target material on the substrate; and
installing a compensation plate between the target and the magnetic field generating device, wherein the compensation plate is comprised of a substrate having at least one magnetic field compensation area thereon, such that the ferromagnetic property of the magnetic field compensation area is different from the ferromagnetic property of the substrate.

2. The method of claim 1, wherein the step of fabricating the compensation plate further comprises:
utilizing the magnetron sputtering coater to perform a sputtering process and cause damage on the surface of the target material; and
forming the magnetic field compensation area at the location of the compensation plate corresponds to the target material with uneven damage.

3. The method of claim 2 further comprising forming the substrate of the compensation plate with a weak or no ferromagnetic material and inserting a strong ferromagnetic material into the area of the substrate having correspondingly greater damage on the target material for forming a magnetic field compensation area.

4. The method of claim 3, wherein the thickness of the inserted area of the compensation plate is approximately equivalent to the thickness of the un-inserted compensation plate.

5. The method of claim 3, wherein the thickness of the strong ferromagnetic material inserted into the magnetic field compensation area increases as the damage of the target material increases.

6. The method of claim 3, wherein the strong ferromagnetic material comprises iron, cobalt, nickel, or a compound material thereof, or Heusler alloy.

7. The method of claim 3, wherein the weak or no ferromagnetic material comprises aluminum, copper, silver, zinc, gold, carbon, lead, magnesium, platinum, chromium, manganese, tin, vanadium, tungsten, or a compound material thereof.

8. The method of claim 2 further comprising forming the substrate of the compensation plate with a strong ferromagnetic material and inserting a weak or no ferromagnetic material into the area of the substrate having correspondingly smaller damage on the target material for forming a magnetic field compensation area.

9. The method of claim 2, wherein the compensation plate is comprised of a high ferromagnetic material and the area on the compensation plate corresponding to the target material with smaller damage is removed for forming the magnetic field compensation area.

10. The method of claim 1, wherein the magnetic field generating device is a magnet.

11. The method of claim 1, wherein after the compensation plate is installed between the magnetic field generating device and the target further comprises:
performing a plurality of the sputtering process for causing damage to the surface of the target material;
adjusting the magnetic field compensation area of the compensation plate according to a damage map; and
reinstalling the adjusted compensation plate between the magnetic field generating device and the target.

12. A method of improving the magnetic field uniformity of an equipment having a magnetic field generating device:
providing an equipment, wherein the equipment comprises a magnetic field generating device and a magnetic field receiving surface;
utilizing the equipment numerous times for obtaining the magnetic field strength distribution of the magnetic field receiving surface;
providing a compensation plate according to the magnetic field strength distribution of the magnetic field receiving surface, such that the area of the compensation plate corresponding to area of the magnetic field receiving surface having a stronger magnetic field comprises a stronger ferromagnetic property, and the area of the compensation plate corresponding to the area of the magnetic field receiving surface having a weaker magnetic field comprises a weaker ferromagnetic property; and
installing the compensation plate between the magnetic field generating device and the magnetic field receiving surface for improving the magnetic field uniformity of the magnetic field receiving surface.

13. A magnetron sputtering coater comprising:
a target, wherein the front of the target further comprises a target material;
a susceptor situated corresponding to the target, wherein the susceptor supports a substrate for depositing a target material thereon;
a magnetic field generating device located on the back of the target for generating a magnetic field and controlling the deposition of the target material; and
a compensation plate installed between the target and the magnetic field generating device, wherein the compensation plate is comprised of a substrate having at least one magnetic field compensation area thereon, such that the ferromagnetic property of the magnetic field compensation area is different from the ferromagnetic property of the substrate.

14. The magnetron sputtering coater of claim 13, wherein the position of the compensation plate is fixed by a slot.

15. The magnetron sputtering coater of claim 13, wherein the magnetic field compensation area is formed corresponding to the location of the uneven damage caused on the surface of the target material after a sputtering process.

16. The magnetron sputtering coater of claim 15, wherein the substrate of the compensation plate is comprised of a weak or no ferromagnetic material and the magnetic field compensation area is formed by inserting a strong ferromagnetic material into the area of the substrate having correspondingly greater damage on the target material.

17. The magnetron sputtering coater of claim 16, wherein the thickness of the inserted area of the compensation plate is approximately equivalent to the thickness of the un-inserted compensation plate.

18. The magnetron sputtering coater of claim 16, wherein the thickness of the strong ferromagnetic material inserted into the magnetic field compensation area increases as the damage of the target material increases.

19. The magnetron sputtering coater of claim 16, wherein the strong ferromagnetic material comprises iron, cobalt, nickel, or a compound material thereof, or Heusler alloy.

20. The magnetron sputtering coater of claim 16, wherein the weak or no ferromagnetic material comprises aluminum, copper, silver, zinc, gold, carbon, lead, magnesium, platinum, chromium, manganese, tin, vanadium, tungsten, or other compound materials.

21. The magnetron sputtering coater of claim 15, wherein the substrate of the compensation plate is comprised of a strong ferromagnetic material and the magnetic field compensation area is formed by inserting a weak or no ferromagnetic material into the area of the substrate having correspondingly smaller damage on the target material.

22. The magnetron sputtering coater of claim 15, wherein the substrate of the compensation plate is comprised of a strong ferromagnetic material and the magnetic field compensation area is formed by removing the area of the substrate having correspondingly smaller damage on the target material.

23. The magnetron sputtering coater of claim 13, wherein the magnetic field generating device is a magnet.
